(19) United States
(12) Patent Application Publication
(10) Pub. No.: US 2026/0314061 A1
(43) Pub. Date: Oct. 8, 2026

(54) SOURCE/DRAIN CONTACT IN STACKED NANOSHEET FETS

(71) Applicant: INTERNATIONAL BUSINESS MACHINES CORPORATION, Armonk, NY (US)

(72) Inventors: Utkarsh Bajpai, Suffern, NY (US); James Patrick Mazza, Saratoga Springs, NY (US); Shahrukh Khan, Sandy Hook, CT (US)

(21) Appl. No.: 19/172,811

(22) Filed: Apr. 8, 2025

(51) Int. Cl. H10D 84/85; H10D 84/01

(52) U.S. Cl. CPC H10D 84/856; H10D 84/0186; H10D 84/851

(57) ABSTRACT

Embodiments of present invention provide a semiconductor structure. The structure includes a nanosheet transistor having a metal gate surrounding a set of nanosheets; a source/drain region at an end surface of the set of nanosheets; and a set of inner spacers separating the source/drain region from the metal gate; a diffusion break adjacent to and separated from the source/drain region by a distance equal to a length of the set of inner spacers; and a frontside source/drain contact in contact with the source/drain region, the frontside source/drain contact having a lower portion at or below a top surface of the source/drain region and horizontally between the source/drain region and the diffusion break. A method of forming the same is also provided.

### BACKGROUND

The present application relates to manufacturing of semiconductor integrated circuits. More particularly, it relates to a method of forming source/drain contact for stacked transistors with diffusion break, and the structure formed thereby.

As semiconductor industry moves towards smaller node, transistors or more specifically field-effect-transistors (FETs) are aggressively scaled to fit into reduced footprint or real estate such as, for example, through the introduction of nanosheet transistors or more specifically nanosheet field-effect-transistors (NSFETs). Moreover, nanosheet transistors may be vertically stacked together to further increase the density of the transistors thereby reducing the overall footprint of a device.

A FET such as a NSFET generally includes a metal gate and source/drain regions adjacent to the metal gate. Contacts such as source/drain contacts and gate contact may be formed to be in contact with the source/drain regions and the metal gate, respectively. In the meantime, the reduction in scale in transistor structure has created source/drain contacts that are ever closer than before to the metal gate, resulting in an increase in parasitic capacitance formed between the metal gate and source/drain contact. The increase in such parasitic capacitance ultimately affects the performance, such as operational speed, of the transistors.

### SUMMARY

Embodiments of present invention provide a semiconductor structure. The structure includes a first nanosheet transistor having a metal gate surrounding a set of nanosheets; a first and a second source/drain region at end surfaces of the set of nanosheets; and a first and a second set of inner spacers separating the first and the second source/drain region, respectively, from the metal gate; a first diffusion break adjacent to and separated from the first source/drain region by a third set of inner spacers; and a first frontside source/drain contact in contact with the first source/drain region, the first frontside source/drain contact having a lower portion below a top surface of the first source/drain region and horizontally between the first source/drain region and the first diffusion break.

In one embodiment, the lower portion of the first frontside source/drain contact has a width that equals to a length of the third set of inner spacers.

In another embodiment, the lower portion of the first frontside source/drain contact has a height that is equal to or larger than a height of an inner spacer of the third set of inner spacers.

In yet another embodiment, a vertical central line of the top portion of the first source/drain contact is not aligned with a vertical central line of the first source/drain region.

According to one embodiment, the semiconductor structure further includes a second diffusion break, the second diffusion break adjacent to and separated from the second source/drain region by a fourth set of inner spacers; and a first backside source/drain contact in contact with a bottom surface of the second source/drain region.

According to another embodiment, the semiconductor structure further includes a second nanosheet transistor having a metal gate surrounding a set of nanosheets and a first and a second source/drain region at end surfaces of the set of nanosheets of the second nanosheet transistor; and a second frontside source/drain contact in contact with a top surface and a portion of a sidewall of the first source/drain region of the second nanosheet transistor, where a top surface of the first frontside source/drain contact and a top surface of the second source/drain contact are substantially coplanar.

In one embodiment, the first and the second source/drain region of the second nanosheet transistor is at a level below, and does not vertically overlap entirely with, the first and the second source/drain region of the first nanosheet transistor.

In another embodiment, at least a portion of the second frontside source/drain contact is in directly contact with the first diffusion break.

According to one embodiment, the semiconductor structure further includes a second backside source/drain contact in contact with a bottom surface of the second source/drain region of the second nanosheet transistor, wherein bottom surfaces of the first and the second backside source/drain contact are substantially coplanar.

Embodiments of present invention further provide a method of forming a semiconductor structure. The method includes forming a nanosheet transistor having a metal gate surrounding a set of nanosheets and a source/drain region at an end surface of the set of nanosheets; forming a diffusion break adjacent to and separated from the source/drain region by a set of inner spacers; and forming a frontside source/drain contact in contact with the source/drain region, the frontside source/drain contact having a lower portion at or below a top surface of the source/drain region and horizontally between the source/drain region and the diffusion break.

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B, 1C and 1D are demonstrative illustrations of various cross-sectional views of a semiconductor structure at a step of manufacturing thereof according to one embodiment of present invention;

FIGS. 2A, 2B, 2C and 2D are demonstrative illustrations of various cross-sectional views of a semiconductor structure at a step of manufacturing thereof, following the step illustrated at FIGS. 1A, 1B, 1C and 1D, according to one embodiment of present invention;

FIGS. 3A, 3B, 3C and 3D are demonstrative illustrations of various cross-sectional views of a semiconductor structure at a step of manufacturing thereof, following the step illustrated at FIGS. 2A, 2B, 2C and 2D, according to one embodiment of present invention;

FIGS. 4A, 4B, 4C and 4D are demonstrative illustrations of various cross-sectional views of a semiconductor structure at a step of manufacturing thereof, following the step illustrated at FIGS. 3A, 3B, 3C and 3D, according to one embodiment of present invention;

FIGS. 5A, 5B, 5C and 5D are demonstrative illustrations of various cross-sectional views of a semiconductor structure at a step of manufacturing thereof, following the step illustrated at FIGS. 4A, 4B, 4C and 4D, according to one embodiment of present invention;

FIGS. 6A, 6B, 6C and 6D are demonstrative illustrations of various cross-sectional views of a semiconductor structure at a step of manufacturing thereof, following the step illustrated at FIGS. 5A, 5B, 5C and 5D, according to one embodiment of present invention;

FIGS. 7A, 7B, 7C and 7D are demonstrative illustrations of various cross-sectional views of a semiconductor structure at a step of manufacturing thereof, following the step illustrated at FIGS. 6A, 6B, 6C and 6D, according to one embodiment of present invention;

FIGS. 8A, 8B, 8C and 8D are demonstrative illustrations of various cross-sectional views of a semiconductor structure at a step of manufacturing thereof, following the step illustrated at FIGS. 7A, 7B, 7C and 7D, according to one embodiment of present invention;

FIGS. 9A, 9B, 9C and 9D are demonstrative illustrations of various cross-sectional views of a semiconductor structure at a step of manufacturing thereof, following the step illustrated at FIGS. 8A, 8B, 8C and 8D, according to one embodiment of present invention;

FIGS. 10A, 10B, 10C and 10D are demonstrative illustrations of various cross-sectional views of a semiconductor structure at a step of manufacturing thereof, following the step illustrated at FIGS. 9A, 9B, 9C and 9D, according to one embodiment of present invention;

FIGS. 11A, 11B, 11C and 11D are demonstrative illustrations of various cross-sectional views of a semiconductor structure at a step of manufacturing thereof, following the step illustrated at FIGS. 10A, 10B, 10C and 10D, according to one embodiment of present invention;

FIGS. 12A, 12B, 12C and 12D are demonstrative illustrations of various cross-sectional views of a semiconductor structure at a step of manufacturing thereof, following the step illustrated at FIGS. 11A, 11B, 11C and 11D, according to one embodiment of present invention;

FIGS. 13A, 13B, 13C and 13D are demonstrative illustrations of various cross-sectional views of a semiconductor structure at a step of manufacturing thereof, following the step illustrated at FIGS. 12A, 12B, 12C and 12D, according to one embodiment of present invention;

FIGS. 14A, 14B, 14C and 14D are demonstrative illustrations of various cross-sectional views of a semiconductor structure at a step of manufacturing thereof, following the step illustrated at FIGS. 13A, 13B, 13C and 13D, according to one embodiment of present invention;

FIGS. 15A, 15B, 15C and 15D are demonstrative illustrations of various cross-sectional views of a semiconductor structure at a step of manufacturing thereof, following the step illustrated at FIGS. 14A, 14B, 14C and 14D, according to one embodiment of present invention;

FIGS. 16A, 16B, 16C and 16D are demonstrative illustrations of various cross-sectional views of a semiconductor structure at a step of manufacturing thereof, following the step illustrated at FIGS. 15A, 15B, 15C and 15D, according to one embodiment of present invention;

FIGS. 17A, 17B, 17C and 17D are demonstrative illustrations of various cross-sectional views of a semiconductor structure at a step of manufacturing thereof, following the step illustrated at FIGS. 16A, 16B, 16C and 16D, according to one embodiment of present invention;

FIGS. 18A, 18B, 18C and 18D are demonstrative illustrations of various cross-sectional views of a semiconductor structure at a step of manufacturing thereof, following the step illustrated at FIGS. 17A, 17B, 17C and 17D, according to one embodiment of present invention;

FIGS. 19A, 19B, 19C and 19D are demonstrative illustrations of various cross-sectional views of a semiconductor structure at a step of manufacturing thereof, following the step illustrated at FIGS. 18A, 18B, 18C and 18D, according to one embodiment of present invention; and

FIG. 20 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms "about" or "substantially" as used herein with regard to thicknesses, widths, percentages, ranges, etc., are meant to denote being close or approximate to, but not exactly. For example, the term "about" or "substantially" as used herein implies that a small margin of error may be present such as, by way of example only, 1% or less than the stated amount. Likewise, the terms "on", “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

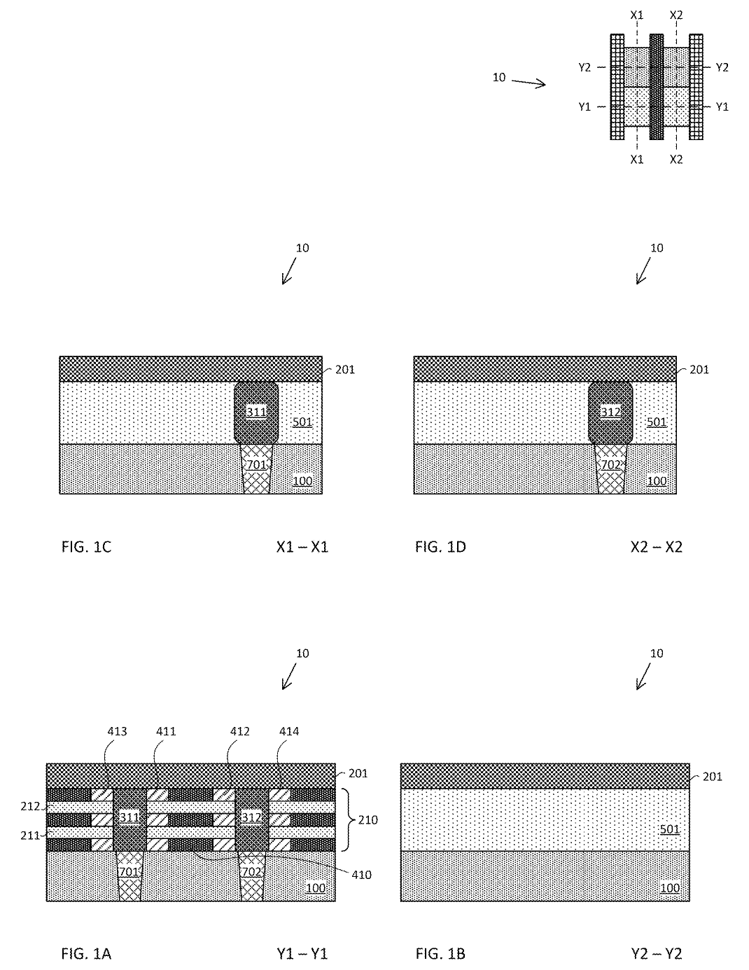

FIGS. 1A, 1B, 1C and 1D are demonstrative illustrations of different cross-sectional views of a semiconductor structure 10 in a step of manufacturing thereof according to one embodiment of present invention. More specifically, FIG. 1A illustrates a cross-sectional view of the semiconductor structure 10 with a cross-section made along a dashed line Y1-Y1 as indicated in a simplified top view of the structure at the upper right corner of the drawing. In other words, the cross-section in FIG. 1A is made across a gate of a bottom nanosheet transistor in a direction along a length of the gate from a first source/drain region to a second source/drain region of the bottom nanosheet transistor. FIG. 1B illustrates a cross-sectional view of the semiconductor structure 10 with a cross-section made along a dashed line Y2-Y2 as indicated in the simplified top view of the structure. In other words, the cross-section in FIG. 1B is made across a gate of a top nanosheet transistor in a direction along a length of the gate from a first source/drain region to a second source/drain region of the top nanosheet transistor. FIG. 1C illustrates a cross-sectional view of the semiconductor structure 10 with a cross-section made along a dashed line X1-X1 as indicated in the simplified top view of the structure. In other words, the cross-section in FIG. 1C is made across the first source/drain regions of the top and bottom nanosheet transistors in a direction along a width of the gates of the top and bottom nanosheet transistors. FIG. 1D illustrates a cross-sectional view of the semiconductor structure 10 with a cross-section made along a dashed line X2-X2 as indicated in the simplified top view of the structure. In other words, the cross-section in FIG. 1D is made across the second source/drain regions of the top and bottom nanosheet transistors in a direction along the width of the gates of the top and bottom nanosheet transistors.

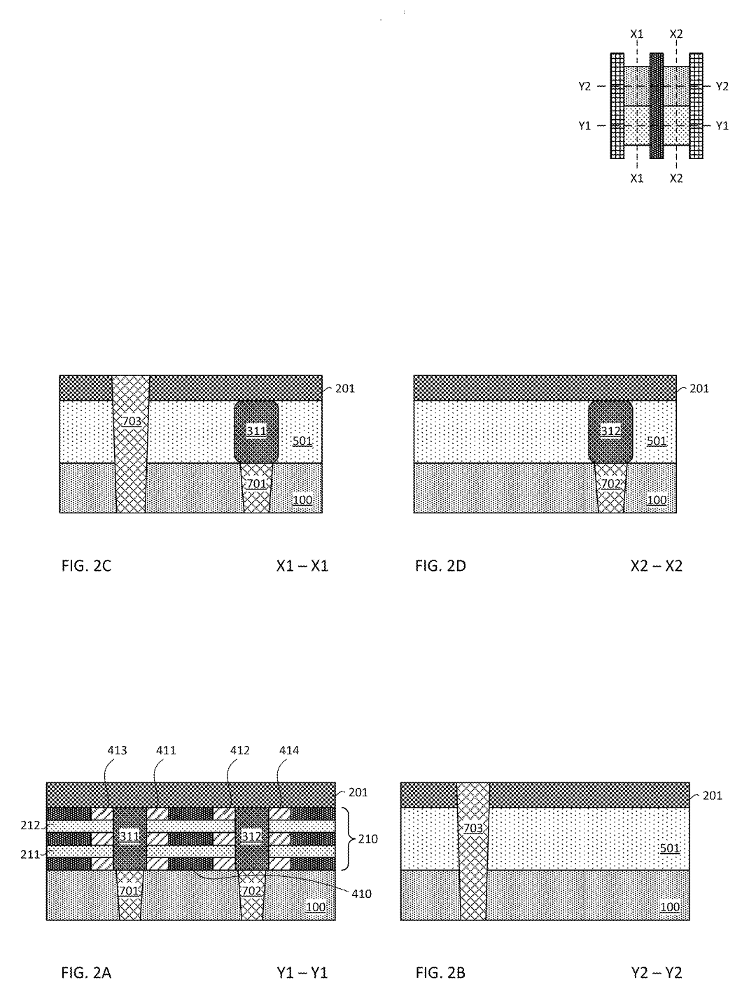

Likewise, FIGS. 2A, 2B, 2C and 2D to FIGS. 19A, 19B, 19C and 19D are demonstrative cross-sectional views of the semiconductor structure 10, at various different manufacturing steps, illustrated in manners similar to FIGS. 1A, 1B, 1C and 1D respectively.

Embodiments of present invention provide forming the semiconductor structure 10 that is demonstratively illustrated to include a top nanosheet transistor and a bottom nanosheet transistor, although embodiments of present invention are not limited in this aspect and may be applied to other types of transistors and/or active devices. More particularly, as is illustrated in FIG. 1A, the semiconductor structure 10 may include a semiconductor substrate 100 and a bottom nanosheet transistor 210 on top of the semiconductor substrate 100. The semiconductor substrate 100 may be a silicon (Si) substrate, a germanium (Ge) substrate, or a silicon-germanium (SiGe) substrate. The bottom nanosheet transistor 210 may include a metal gate 410 surrounding a set of nanosheets including nanosheets 211 and 212. The bottom nanosheet transistor 210 may further include a first source/drain region 311 and a second source/drain region 312 adjacent to and separated from the metal gate 410, respectively, by a first set of inner spacers 411 and a second set of inner spacers 412.

The first source/drain region 311 may be further separated from a dummy metal gate by a third set of inner spacers 413 and the second source/drain region 312 may be further separated from a dummy metal gate by a fourth set of inner spacers 414. The first, second, third, and fourth sets of inner spacers may have a substantially same length, measured from the metal gate 410 or the dummy metal gates to the first or the second source/drain region 311 or 312, respectively.

The bottom nanosheet transistor 210 may be embedded in a dielectric layer 501 and covered, at a top surface thereof, by a middle-dielectric-isolation (MDI) layer 201. According to one embodiment, the MDI layer 201 may be a layer of bonding oxide that is used to, in addition to insulate, bond a top nanosheet transistor to the bottom nanosheet transistor 210. In one embodiment, a first and a second placeholder 701 and 702 may be formed in the semiconductor substrate 100. The first and the second placeholder 701 and 702 may be made of dielectric materials such as, for example, silicon-nitride (SiN), silicon-oxide (SiOx), silicon-carbide (SiC), silicon-oxycarbide (SiOC), silicon-oxycarbonitride (SiOCN), or other suitable dielectric materials including low-k or ultra-low-k dielectric materials. Alternatively, the first and the second placeholder 701 and 702 may be made of semiconductor material such as silicon-germanium (SiGe). The first and the second placeholder 701 and 702 may be formed directly underneath the first and the second source/drain region 311 and 312 such that they may be selectively removed later in a process of forming backside source/drain contacts as being described below in more details. In some embodiments, the bottom nanosheet transistor 210 may be referred to as a first nanosheet transistor or a second nanosheet transistor as well (while a top nanosheet transistor may be referred to as a second nanosheet transistor or a first nanosheet transistor correspondingly).

FIGS. 2A, 2B, 2C and 2D are demonstrative illustrations of various cross-sectional views of a semiconductor structure at a step of manufacturing thereof, following the step illustrated at FIGS. 1A, 1B, 1C and 1D, according to one embodiment of present invention. More particularly, embodiments of present invention provide forming one or more placeholders for a top nanosheet transistor that is to be formed on top of, or above, the bottom nanosheet transistor 210. For example, a third placeholder 703 may be formed through the MDI layer 201, the dielectric layer 501 that surrounds the bottom nanosheet transistor 210, and the semiconductor substrate 100, as are illustrated in FIG. 2B and FIG. 2C. The third placeholder 703 may be formed through a lithographic patterning process, which is then followed by a selective etch and deposition process. A chemical-mechanical-polishing (CMP) process may be applied to planarize a top surface of the third placeholder 703 to be substantially coplanar with the MDI layer 201.

The third placeholder 703 may be made of dielectric material such as SiN, SiOx, SiC, SiOC, SiOCN or other suitable low-k or ultra-low-k dielectric materials, or semiconductor materials such as SiGe. In one embodiment, the material of the third placeholder 703 may be different from those of the MDI layer 201 and the dielectric layer 501 such that the third placeholder 703 may be selectively removed, in a later stage, as being described below in more details.

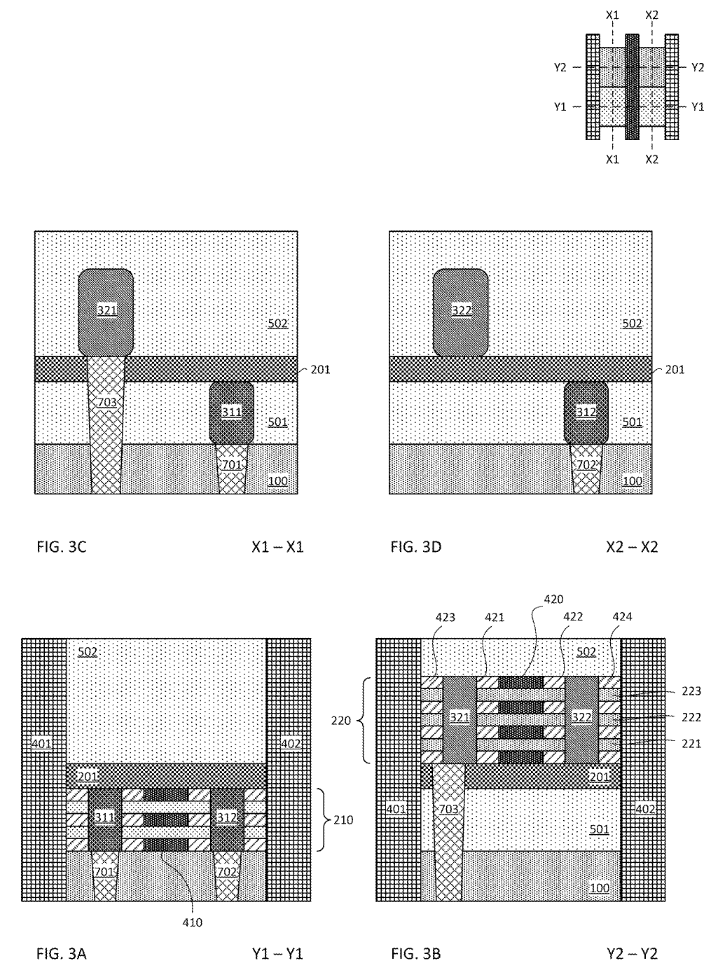

FIGS. 3A, 3B, 3C and 3D are demonstrative illustrations of various cross-sectional views of a semiconductor structure at a step of manufacturing thereof, following the step illustrated at FIGS. 2A, 2B, 2C and 2D, according to one embodiment of present invention. More particularly, embodiments of present invention provide forming a top nanosheet transistor 220, which may be referred to, hereinafter, as either a first nanosheet transistor or a second nanosheet transistor in relationship to the bottom nanosheet transistor. The top nanosheet transistor 220 may include a metal gate 420 surrounding a set of nanosheets including nanosheets 221, 222 and 223. The top nanosheet transistor 220 may further include a first source/drain region 321 and a second source/drain region 322 adjacent to and separated from the metal gate 420, respectively, by a first set of inner spacers 421 and a second set of inner spacers 422. The first and second sets of inner spacers 421 and 422, together with a third set of inner spacers 423 and a fourth set of inner spacers 424 may have a substantially same length, measured in a direction from the metal gate 420 to the first or the second source/drain region 321 or 322, or from the first or the second source/drain region 321 or 322 to an adjacent dummy gate.

The top nanosheet transistor 220 may be formed on top of, or above, the bottom nanosheet transistor 210 but may not overlap completely with the bottom nanosheet transistor 210 in a vertical direction. As are demonstratively illustrated in FIGS. 3A and 3B, the metal gate 420 and the set of nanosheets 221, 222 and 223 of the top nanosheet transistor 220 are at a level above the metal gate 410 and the set of nanosheets 211 and 212 but not, in a vertical direction, entirely directly above the metal gate 410 and the set of nanosheets 211 and 212 of the bottom nanosheet transistor 210. For example, nanosheets of the top nanosheet transistor 220 may not entirely, or at most partially, vertically overlap with nanosheets of the bottom nanosheet transistor 210. Source/drain regions 321 and 322 may not entirely, or at most partially, vertically overlap with source/drain regions 311 and 312 of the bottom nanosheet transistor 210. The top nanosheet transistor 220 is embedded or surrounded by a dielectric layer 502, and the dielectric layer 502 is directly above the bottom nanosheet transistor 210. The top nanosheet transistor 220 is directly above the dielectric layer 501 and covered by the dielectric layer 502.

Embodiments of present invention further provide forming one or more diffusion breaks in one or more areas of the dummy gates. For example, a first diffusion break 401 may be formed in the area of the first dummy gate next to the first source/drain region 311 of the bottom nanosheet transistor 210 and a dummy gate next to the first source/drain region 321 of the top nanosheet transistor 220. The first diffusion break 401 may be adjacent to but separated from the first source/drain region 311 or the first source/drain region 321 by a distance that is equal to the length of the third set of inner spacers 413 or the third set of inner spacers 423. Similarly, a second diffusion break 402 may be formed in the area of the second dummy gate next to the second source/drain region 312 of the bottom nanosheet transistor 210 and a dummy gate next to the second source/drain region 322 of the top nanosheet transistor 220. The second diffusion break 402 may be adjacent to but separated from the second source/drain region 312 or the second source/drain region 322 by a distance that is equal to the length of the fourth set of inner spacers 414 or the fourth set of inner spacers 424.

According to one embodiment, as is demonstratively illustrated in FIG. 3B, the previously created third placeholder 703 may not be symmetrically situated underneath the first source/drain region 321. In other words, a vertical centra line of the third placeholder 703 may not align with a vertical central line of the first source/drain region 321 of the top nanosheet transistor 220, in a direction of the length of the metal gate 420 but may shift or situate more towards the first diffusion break 401. This shift results in an increase in spacing between the metal gate 420 and the third placeholder 703. This third placeholder 703 may later be replaced with a backside source/drain contact as being described below in more details. The increasing in spacing consequently reduces a parasitic capacitance between the metal gate 420 and the backside source/drain contact.

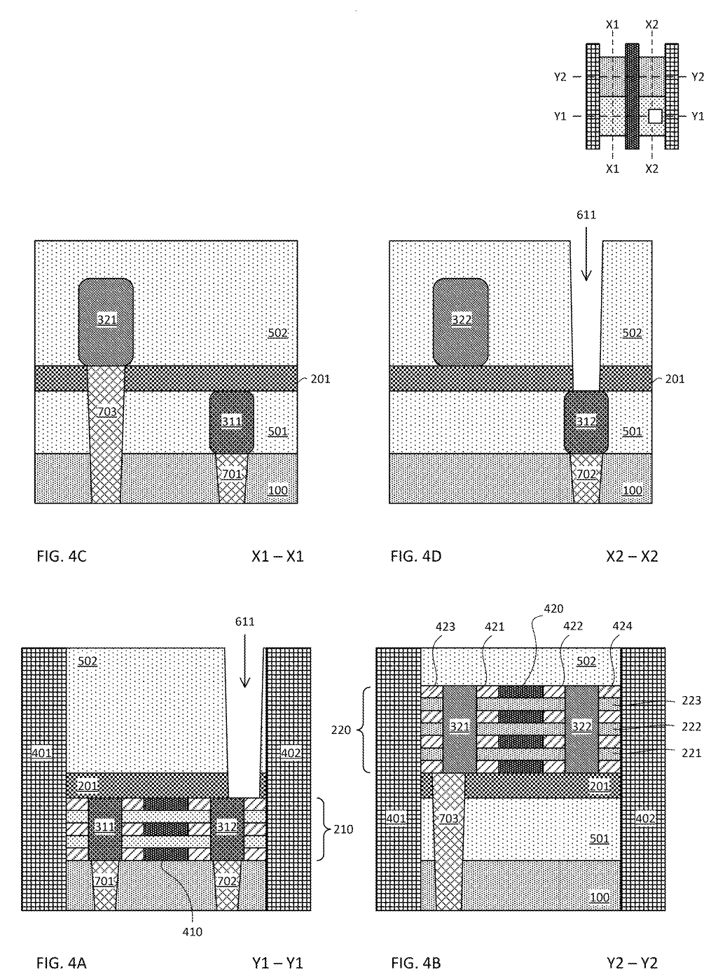

FIGS. 4A, 4B, 4C and 4D are demonstrative illustrations of various cross-sectional views of a semiconductor structure at a step of manufacturing thereof, following the step illustrated at FIGS. 3A, 3B, 3C and 3D, according to one embodiment of present invention. More particularly, embodiments of present invention provide creating a contact opening 611 through the dielectric layer 502 and the MDI layer 201, in an area generally above the second source/drain region 312 of the bottom nanosheet transistor 210. The contact opening 611 may not be symmetrically above the second source/drain region 312 with respect to a vertical central line thereof, of the bottom nanosheet transistor 210 and may be situated more towards the second diffusion break 402. Consequently, the contact opening 611 may expose only a portion of a top surface, that is closer to the second diffusion break 402 than rest of the top surface, of the second source/drain region 312 of the bottom nanosheet transistor 210. In the meantime, the contact opening 611 exposes at least a portion of the fourth set of inner spacers 414.

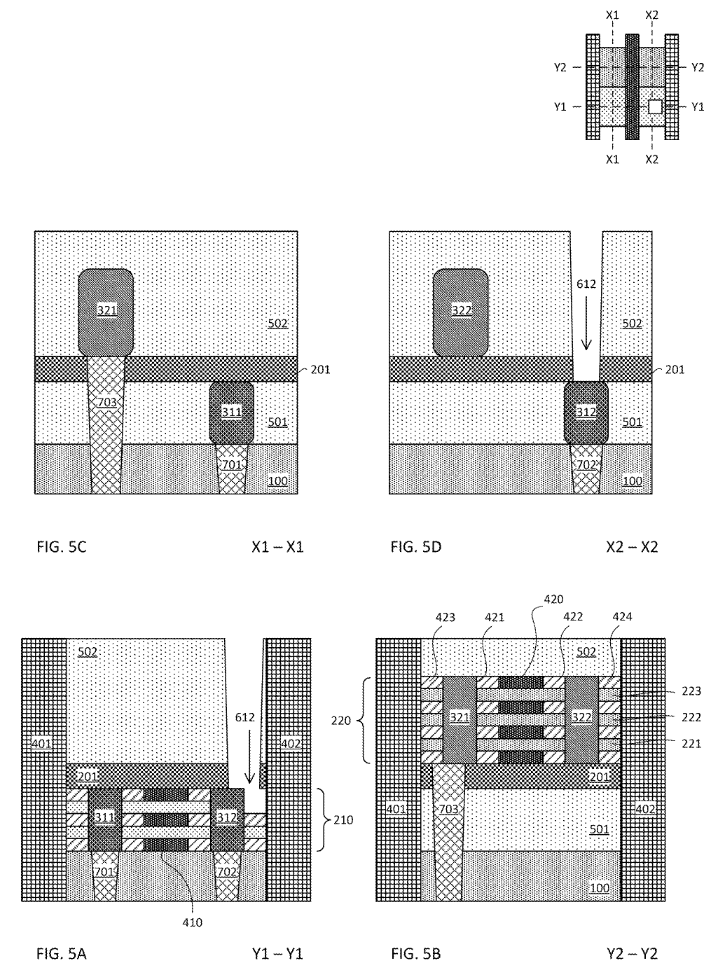

FIGS. 5A, 5B, 5C and 5D are demonstrative illustrations of various cross-sectional views of a semiconductor structure at a step of manufacturing thereof, following the step illustrated at FIGS. 4A, 4B, 4C and 4D, according to one embodiment of present invention. More particularly, embodiments of present invention provide removing, through the contact opening 611 in one or more selective etch processes, one or more inner spacers of the fourth set of inner spacers 414 exposed by the contact opening 611 and removing portions of the nanosheets exposed by the removal of the one or more inner spacers such as removing a portion of the nanosheet 212. The removal of the one or more inner spacers and the portion of the nanosheet 212 expands the contact opening 611 into a contact opening 612 that exposes a portion of sidewall of the second source/drain region 312 of the bottom nanosheet transistor 210 and exposes a portion of sidewall of the second diffusion break 402.

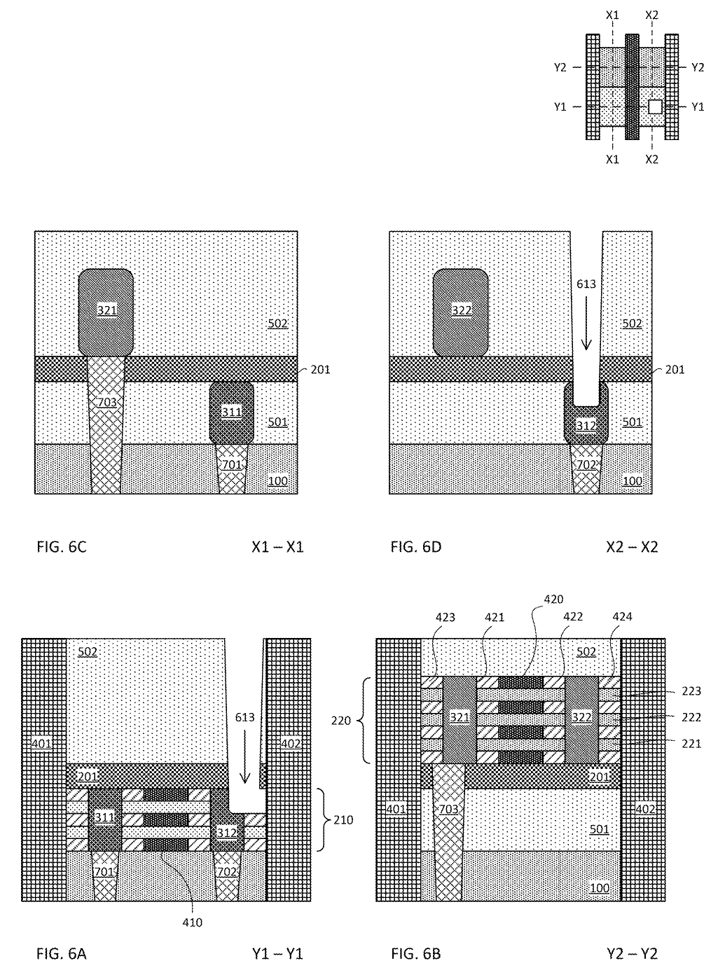

FIGS. 6A, 6B, 6C and 6D are demonstrative illustrations of various cross-sectional views of a semiconductor structure at a step of manufacturing thereof, following the step illustrated at FIGS. 5A, 5B, 5C and 5D, according to one embodiment of present invention. More particularly, embodiments of present invention provide, optionally, gouging the exposed corner of the second source/drain region 312 of the bottom nanosheet transistor 210 to expand the contact opening 612 into a contact opening 613. The contact opening 613, with the second source/drain region 312 being gouged, helps improve conductivity between a first frontside source/drain contact, to be formed later in the contact opening 613, and the second source/drain region 312 of the bottom nanosheet transistor 210.

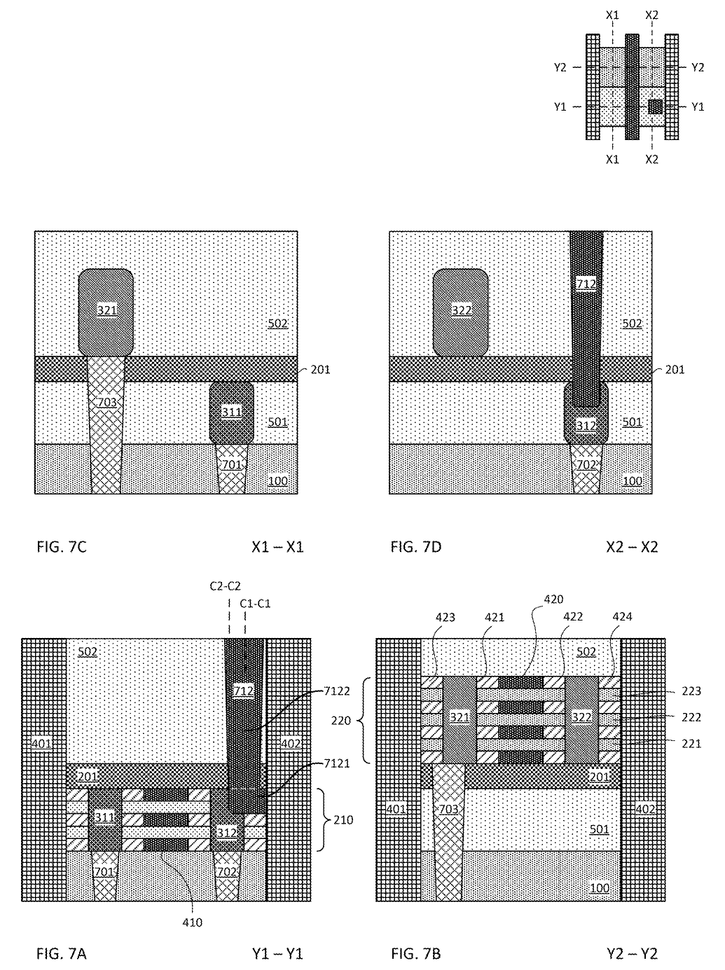

FIGS. 7A, 7B, 7C and 7D are demonstrative illustrations of various cross-sectional views of a semiconductor structure at a step of manufacturing thereof, following the step illustrated at FIGS. 6A, 6B, 6C and 6D, according to one embodiment of present invention. More particularly, embodiments of present invention provide performing metallization of the contact opening 613 by depositing one or more conductive materials into the contact opening 613 to form a first frontside source/drain contact 712. The conductive material may include, for example, tungsten (W), copper (Cu), cobalt (Co), aluminum (Al) or other suitable conductive materials and may be deposited through, for example, an atomic-layer-deposition (ALD) process, a chemical-vapor-deposition (CVD) process, a physical-vapor-deposition (PVD) process, or any other currently existing or future developed processes. A CMP process may be subsequently applied to planarize a top surface of the first frontside source/drain contact 712.

The first frontside source/drain contact 712 may have a lower portion 7121 below and a top portion 7122 above the top surface of the second source/drain region 312 of the bottom nanosheet transistor 210. The lower portion 7121 of the first frontside source/drain contact 712 may be between the second source/drain region 312 and the second diffusion break 402 and have a width that is larger, bigger, or longer than the length of the fourth set of inner spacers 414. The lower portion 7121 of the first frontside source/drain contact 712 may have a height that is equal to or larger than at least a height of one of the inner spacers. For example, the lower portion 7121 of the first frontside source/drain contact 712 may have a height, as is illustrated in FIG. 7A, that equals to the sum of heights of one inner spacer and one nanosheet.

On the other hand, a central line C1-C1 of the upper portion 7122 of the first frontside source/drain contact 712, as is demonstratively illustrated in FIG. 7A, may not be aligned with a central line C2-C2 of the second source/drain region 312 of the bottom nanosheet transistor 210 and may be situated towards the second diffusion break 402. The central line C1-C1 refers to a central line of the structure of the upper portion 7122 of the first frontside source/drain contact 712 when it is looked at in an orientation as being illustrated in FIG. 7A. Similarly, the central line C2-C2 refers to a central line of the structure of the second source/drain region 312 when it is looked at in an orientation as being illustrated in FIG. 7A.

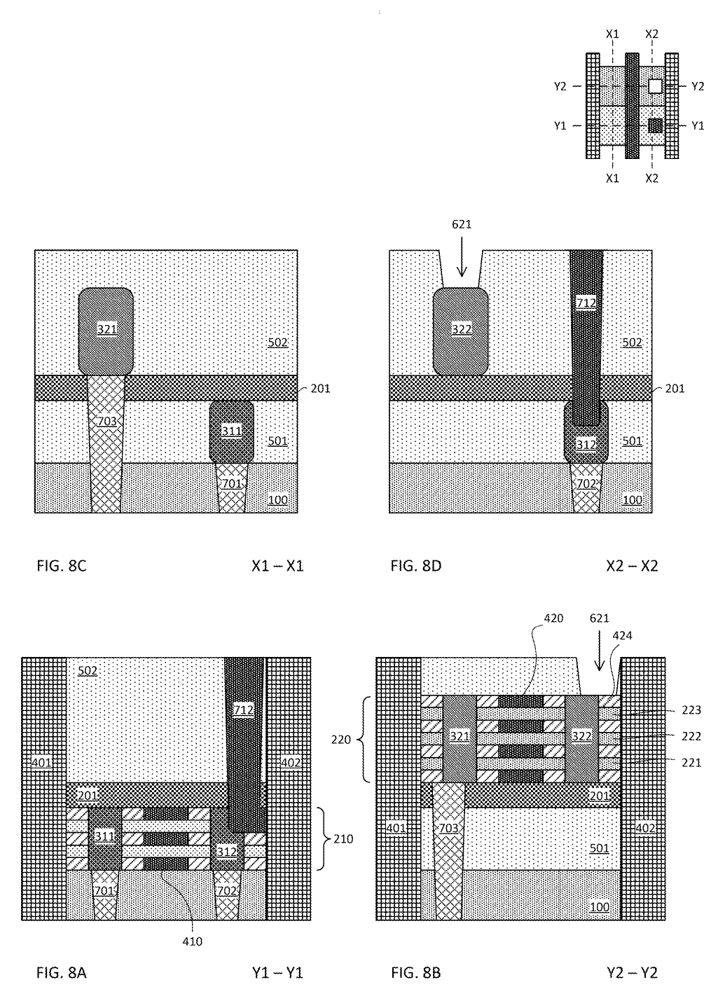

FIGS. 8A, 8B, 8C and 8D are demonstrative illustrations of various cross-sectional views of a semiconductor structure at a step of manufacturing thereof, following the step illustrated at FIGS. 7A, 7B, 7C and 7D, according to one embodiment of present invention. More particularly, embodiments of present invention provide creating a contact opening 621 through the dielectric layer 502 above the top nanosheet transistor 220 to expose a portion of the second source/drain region 322 and at least a portion of the fourth set of inner spacers 424 between the second source/drain region 322 and the second diffusion break 402. The opening 621 may be created to be asymmetric to the second source/drain region 322 with respect to a vertical central line thereof in a cross-section illustrated in FIG. 8B, to shift or be situated more towards the second diffusion break, thereby increasing a spacing between the metal gate 420 and the opening 621 and a second frontside source/drain contact subsequently formed therein, consequently reducing the parasitic capacitance between the metal gate 420 and the first frontside source/drain contact.

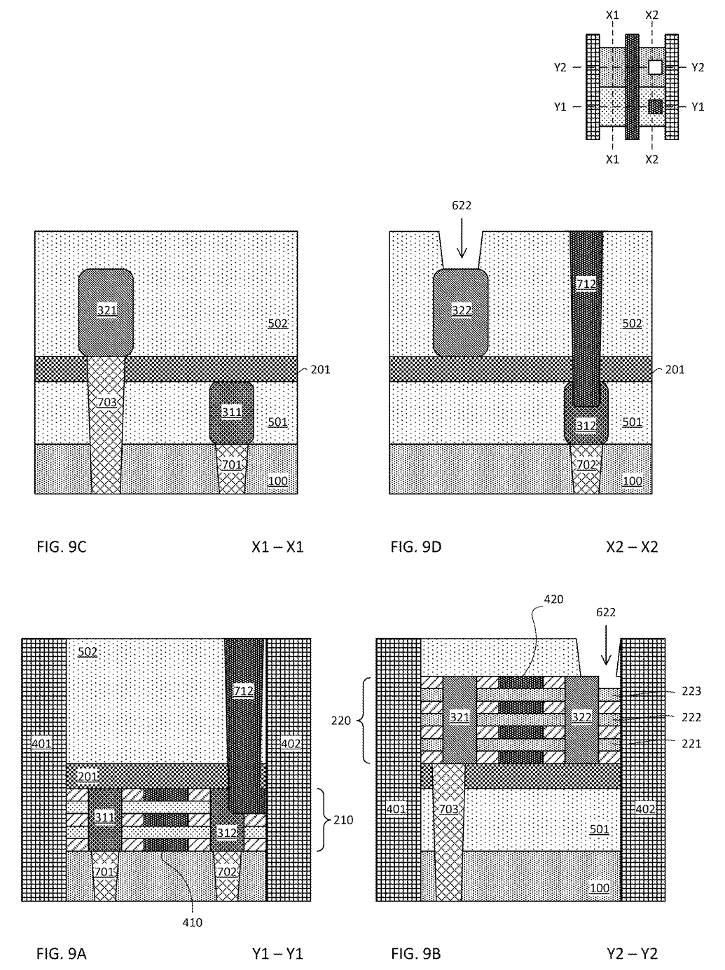

FIGS. 9A, 9B, 9C and 9D are demonstrative illustrations of various cross-sectional views of a semiconductor structure at a step of manufacturing thereof, following the step illustrated at FIGS. 8A, 8B, 8C and 8D, according to one embodiment of present invention. More particularly, embodiments of present invention provide removing, through the opening 621 in a selective etch process, at least one inner spacer of the fourth set of inner spacers 424 exposed by the opening 621, thereby expanding the opening 621 into an opening 622 that exposes a corner of the second source/drain region 322 and a portion of sidewall of the second diffusion break 402. Additionally, as in one embodiment, exposed portions of the nanosheets 223, 222, and/or 221 and one or more inner spacers of the fourth set of inner spacers 424, between the second source/drain region 322 and the second diffusion break 402, may be further removed to expand the opening 622.

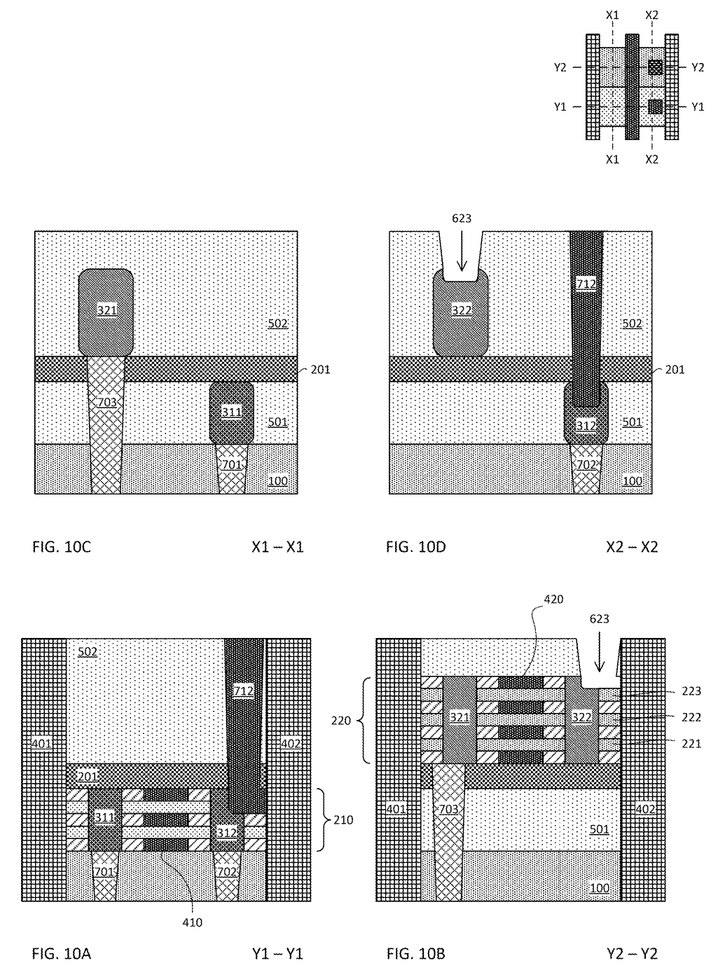

FIGS. 10A, 10B, 10C and 10D are demonstrative illustrations of various cross-sectional views of a semiconductor structure at a step of manufacturing thereof, following the step illustrated at FIGS. 9A, 9B, 9C and 9D, according to one embodiment of present invention. More particularly, embodiments of present invention provide, optionally, gouging the exposed corner of the second source/drain region 322 of the top nanosheet transistor 220 to expand the opening 622 into an opening 623. The opening 623, with the corner of the second source/drain region 322 being gouged, helps improve conductivity between a second frontside source/drain contact, to be formed later in the opening 623, and the second source/drain region 322 of the top nanosheet transistor 220.

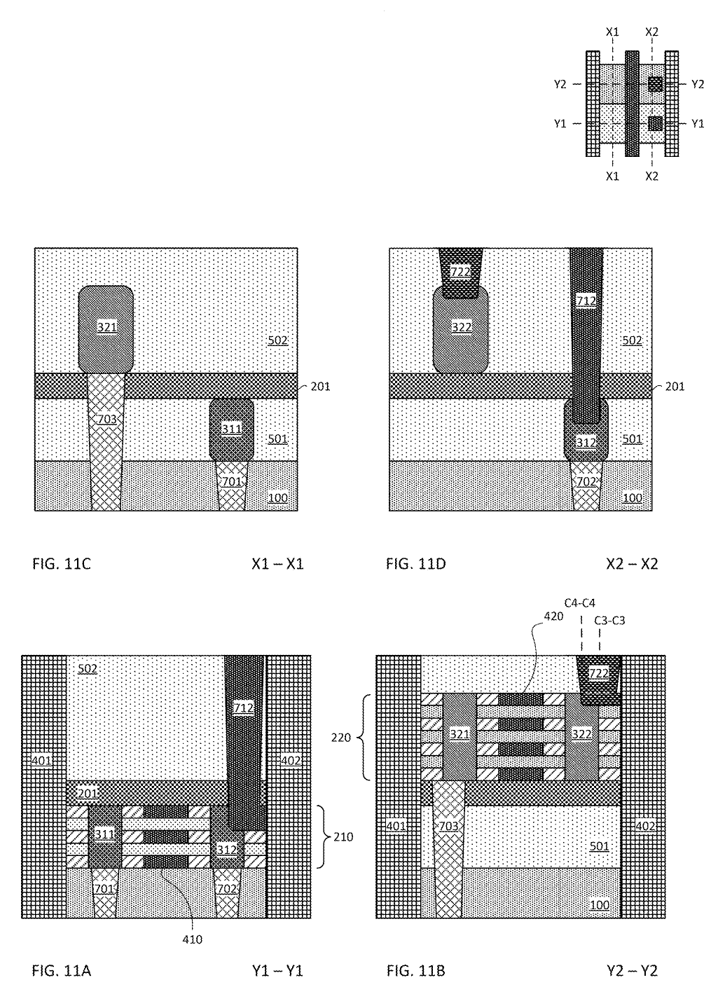

FIGS. 11A, 11B, 11C and 11D are demonstrative illustrations of various cross-sectional views of a semiconductor structure at a step of manufacturing thereof, following the step illustrated at FIGS. 10A, 10B, 10C and 10D, according to one embodiment of present invention. More particularly, embodiments of present invention provide performing metallization of the opening 623 by depositing one or more conductive materials into the opening 623 to form a second frontside source/drain contact 722. The conductive material may include, for example, W, Cu, Co, Al or other suitable conductive materials and may be deposited through, for example, an ALD process, a CVD process, a PVD process, or any other currently existing or future developed processes. A CMP process may subsequently be applied to planarize a top surface of the second frontside source/drain contact 722.

Similar to the first frontside source/drain contact 712, the second frontside source/drain contact 722 may have a lower portion below a top surface of the second source/drain region 322 of the top nanosheet transistor 220. The lower portion may be between the second source/drain region 322 and the second diffusion break 402, and may have a width that is either equal to the length of the fourth set of inner spacers 424 when the second source/drain region 322 is not gouged, or a width that is larger than the length of the fourth set of inner spacers 424 when the second source/drain region 322 is gouged. The second frontside source/drain contact 722 may have an upper portion above the top surface of the second source/drain region 322 of the top nanosheet transistor 220. A central line C3-C3 of the upper portion of the second frontside source/drain contact 722, as is demonstratively illustrated in FIG. 11B, may not be aligned with a central line C4-C4 of the second source/drain region 322 and may be situated towards the second diffusion break 402. In one embodiment, a top surface of the first frontside source/drain contact 712 and a top surface of the second source/drain contact 722 may be substantially coplanar. The central lines C3-C3 and C4-C4 refer to central lines of the upper portion of the second frontside source/drain contact 722 and the second source/drain region 322, respectively, when they are viewed at the orientation as being demonstratively illustrated in FIG. 11B.

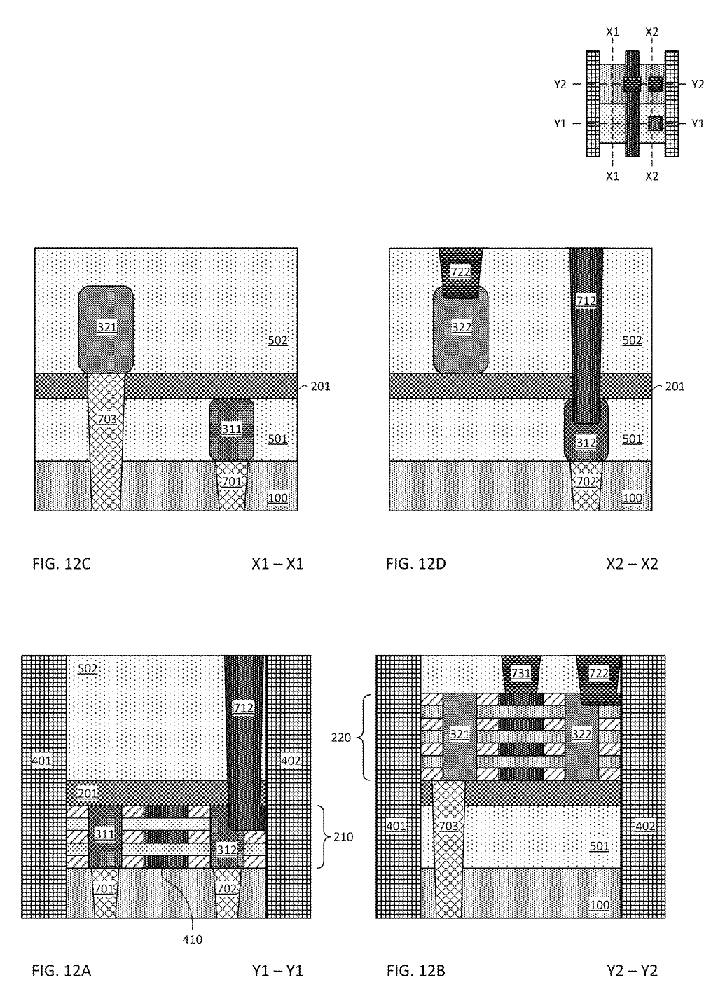

FIGS. 12A, 12B, 12C and 12D are demonstrative illustrations of various cross-sectional views of a semiconductor structure at a step of manufacturing thereof, following the step illustrated at FIGS. 11A, 11B, 11C and 11D, according to one embodiment of present invention. More particularly, embodiments of present invention provide forming a gate contact 731 of conductive material through the dielectric layer 502 in contact with the metal gate 420 of the top nanosheet transistor 220. Other gate contacts may be formed at this stage as well.

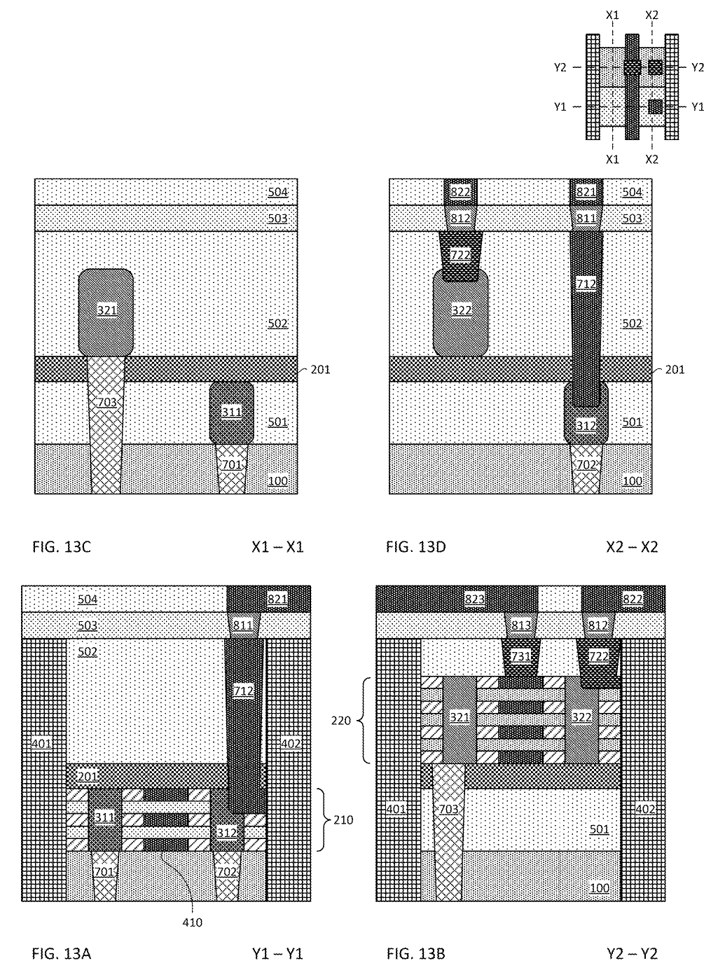

FIGS. 13A, 13B, 13C and 13D are demonstrative illustrations of various cross-sectional views of a semiconductor structure at a step of manufacturing thereof, following the step illustrated at FIGS. 12A, 12B, 12C and 12D, according to one embodiment of present invention. More particularly, embodiments of present invention provide forming a frontside back-end-of-line (BEOL) structure including one or more metal lines 821, 822, and 823 and one or more vias 811, 812, and 813 that conductively connect the one or more metal lines 821, 822, and 823, for example, to the first and second frontside source/drain contacts 712 and 722 and/or the gate contact 731. The vias 811, 812, and 813 and the one or more metal lines 821, 822, and 823 may be formed inside, or be embedded inside, one or more dielectric layers such as dielectric layers 503 and 504.

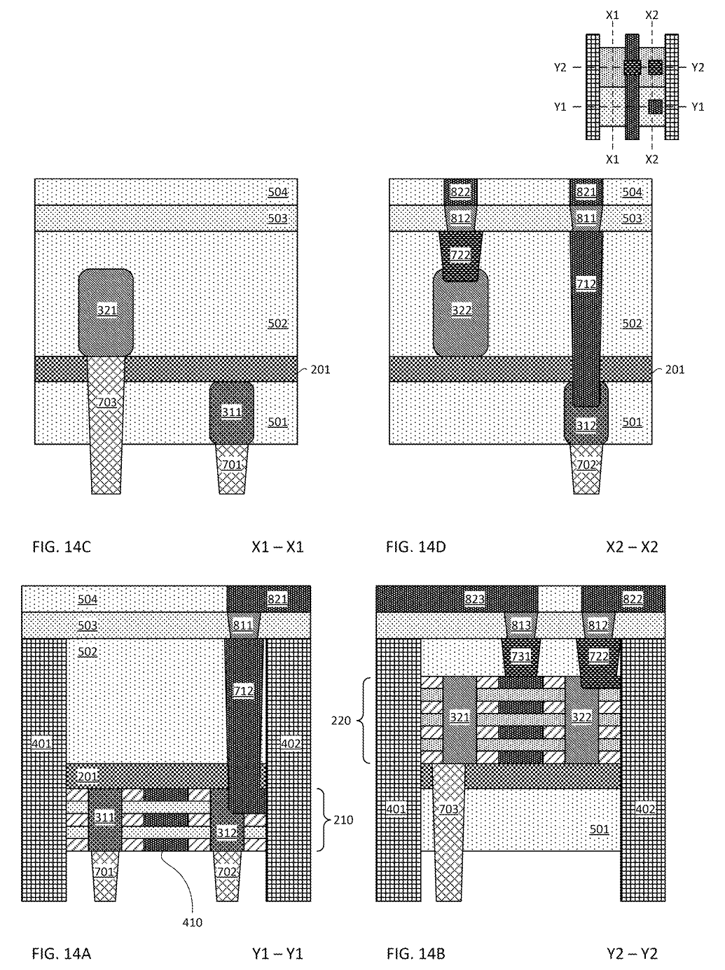

FIGS. 14A, 14B, 14C and 14D are demonstrative illustrations of various cross-sectional views of a semiconductor structure at a step of manufacturing thereof, following the step illustrated at FIGS. 13A, 13B, 13C and 13D, according to one embodiment of present invention. More particularly, embodiments of present invention provide processing the semiconductor structure 10 from the backside of the semiconductor substrate 100 to form one or more backside source/drain contacts. In doing so, embodiments of present invention provide removing the semiconductor substrate 100, through an etch process that is selective to the first, second, and third placeholders 701, 702 and 703 and to the first and second diffusion breaks 401 and 402, stopping at the dielectric layer 501 and the bottom nanosheet transistor 210. The removal of the semiconductor substrate 100 by the selective etch process may be based upon etch selectivity among different materials such as between, for example, Si of the semiconductor substrate 100 and SiN of the placeholders.

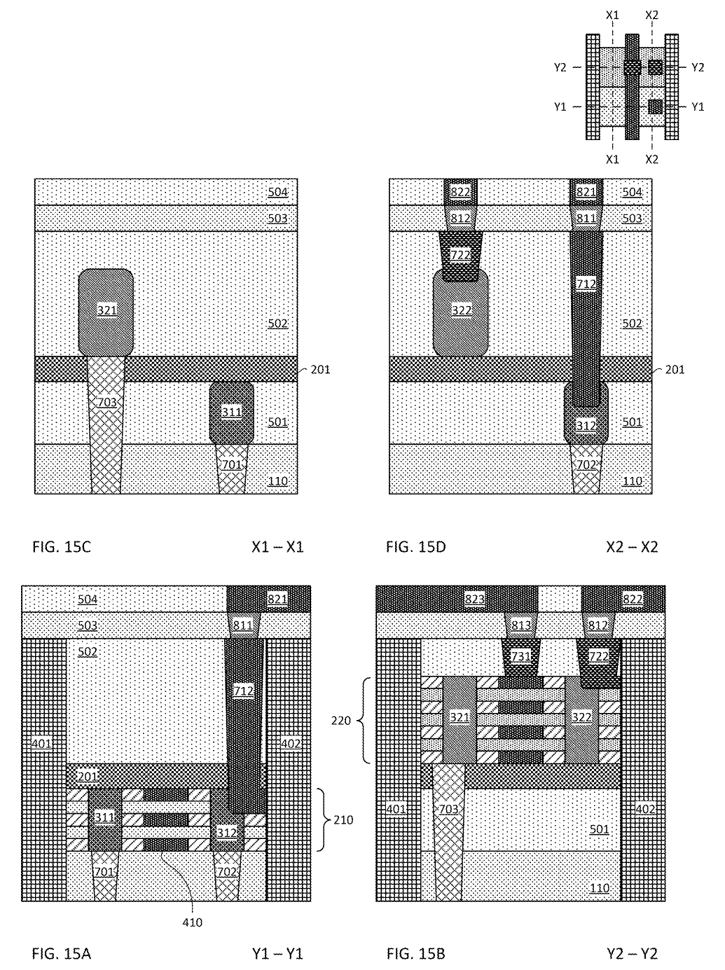

FIGS. 15A, 15B, 15C and 15D are demonstrative illustrations of various cross-sectional views of a semiconductor structure at a step of manufacturing thereof, following the step illustrated at FIGS. 14A, 14B, 14C and 14D, according to one embodiment of present invention. More particularly, embodiments of present invention provide covering the exposed bottom nanosheet transistor 210 and the first and second placeholders 701 and 702 and the partially exposed third placeholders 703 with a dielectric material, for example through a deposition process, and subsequently applying a CMP process to planarize a top surface (shown in FIGS. 15A-15D as a bottom surface) of the dielectric material thereby forming a dielectric layer 110. Material of the dielectric layer 110, and that of the dielectric layer 501, may be different from that of the first, second, and third placeholders 701, 702 and 703. For example, the first, second, and third placeholders 701, 702 and 703 may be made of SiN and the dielectric layers 110 and 501 may be made of SiOx such that they may have or exhibit different etch rate or etch selectivity under certain selective etch conditions. The different etch selectivity facilitates next step or steps of forming one or more backside source/drain contacts as being described below in more details.

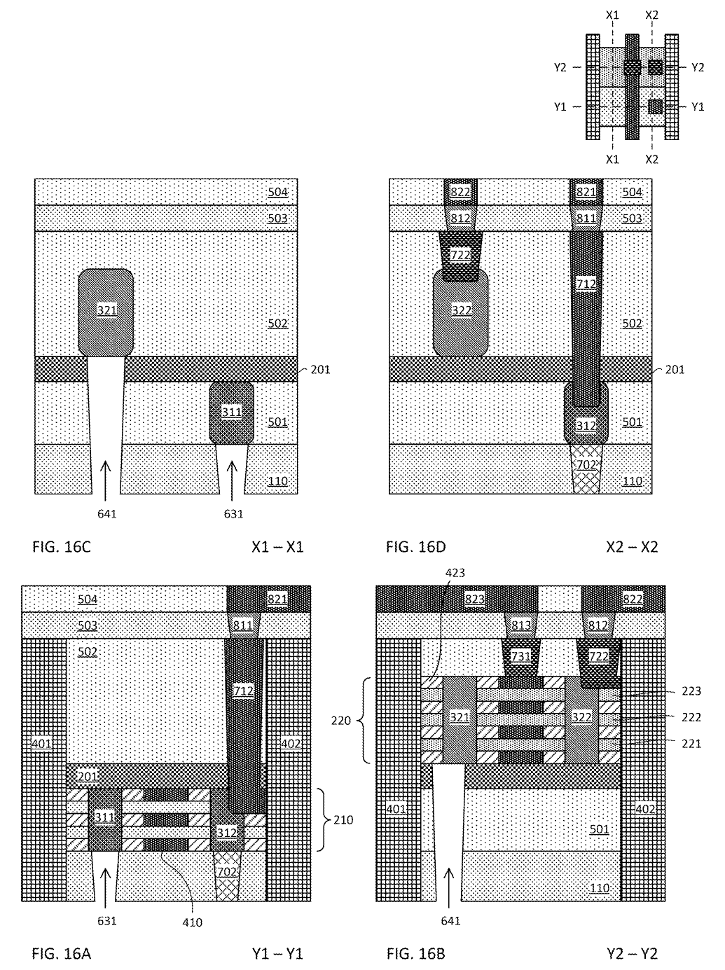

FIGS. 16A, 16B, 16C and 16D are demonstrative illustrations of various cross-sectional views of a semiconductor structure at a step of manufacturing thereof, following the step illustrated at FIGS. 15A, 15B, 15C and 15D, according to one embodiment of present invention. More particularly, embodiments of present invention provide applying a selective etch process to selectively remove one or more of the first, second, and third placeholders 701, 702 and 703 that were surrounded by the dielectric layer 110 and the dielectric layer 501. For example, the first and the third placeholder 701 and 703 may be selectively removed or etched away to create contact openings 631 and 641. The contact opening 631 may expose a bottom surface of the first source/drain region 311 of the bottom nanosheet transistor 210. In the meantime, due to the offset, intentionally created according to embodiments of present invention, between vertical central lines of the third placeholder 703 and the first source/drain region 321 of the top nanosheet transistor 220 as illustrated in FIG. 16B, the contact opening 641 may expose a portion of the bottom surface of the first source/drain region 321 and at least a portion of the third set of inner spacers 423 between the first source/drain region 321 and the first diffusion break 401. In other words, the vertical central line of the contact opening 641 is not aligned with the vertical central line of the first source/drain region 321 and shifts or is situated more towards the first diffusion break 401.

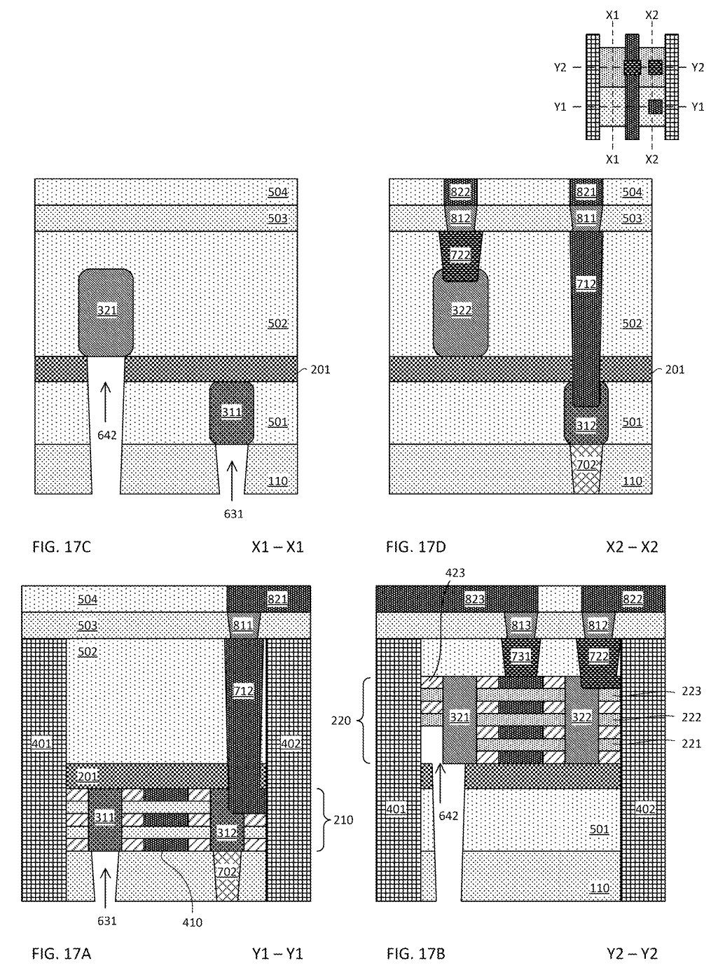

FIGS. 17A, 17B, 17C and 17D are demonstrative illustrations of various cross-sectional views of a semiconductor structure at a step of manufacturing thereof, following the step illustrated at FIGS. 16A, 16B, 16C and 16D, according to one embodiment of present invention. More particularly, embodiments of present invention provide removing, through the contact opening 641 in one or more selective etch processes, one or more inner spacers of the third set of inner spacers 423 exposed by the contact opening 641 and removing portions of the nanosheets exposed by the removal of the one or more inner spacers such as a portion of the nanosheet 221. The removal of the one or more inner spacers and portions of the nanosheets expands the contact opening 641 into a contact opening 642 that exposes a portion of sidewall of the first source/drain region 321 of the top nanosheet transistor 220 and exposes a portion of sidewall of the first diffusion break 401. In one embodiment, the contact opening 631 is fully underneath the first source/drain region 311 of the bottom nanosheet transistor 210.

The contact opening 642 may expose a lower-left corner of the first source/drain region 321 of the top nanosheet transistor 220, as is demonstratively illustrated in FIG. 17B. Optionally, a gouging process may be applied to etch away at least some of this lower-left corner of the first source/drain region 321 to further reduce contact resistance between a backside source/drain contact, to be formed in the contact opening 642, and the first source/drain region 321.

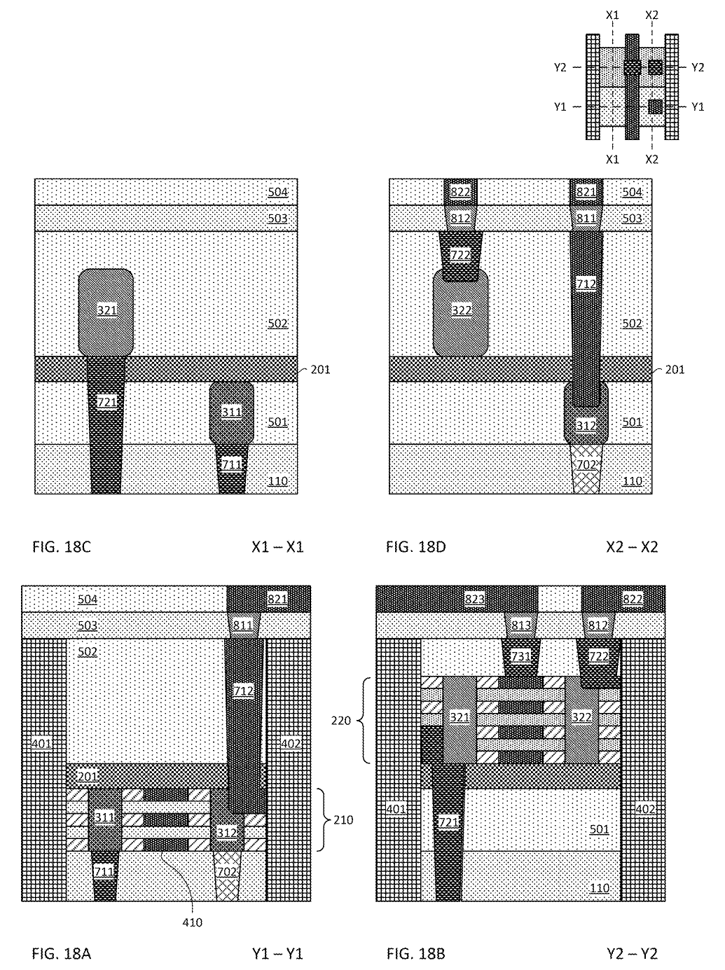

FIGS. 18A, 18B, 18C and 18D are demonstrative illustrations of various cross-sectional views of a semiconductor structure at a step of manufacturing thereof, following the step illustrated at FIGS. 17A, 17B, 17C and 17D, according to one embodiment of present invention. More particularly, embodiments of present invention provide performing metallization of the contact openings 631 and 642 by depositing one or more conductive materials into the contact openings 631 and 642 to form one or more backside source/drain contacts such as, for example, a first and a second backside source/drain contact 711 and 721. The conductive material may include, for example, W, Cu, Co, Al or other suitable conductive materials and may be deposited through, for example, an ALD process, a CVD process, a PVD process, or any other currently existing or future developed processes. After the deposition, a CMP process may be applied to planarize a top surface (shown in FIGS. 18A-18D as a bottom surface) of the first and the second backside source/drain contact 711 and 721.

As is demonstratively illustrated in FIG. 18B, the second backside source/drain contact 721 may have an upper portion above, and a lower portion below, the bottom surface of the first source/drain region 321 of the top nanosheet transistor 220. The upper portion may be between the first diffusion break 401 and the first source/drain region 321 and, when the first source/drain region 321 is not gouged, have a width that equals to the length of the third set of inner spacers 423. The upper portion may have a height that is equal to or larger than at least a thickness of one of the inner spacers. For example, the upper portion may have a height, as is illustrated in FIG. 18B, that equals to the sum of thickness of two inner spacers and one nanosheet. On the other hand, a central line of the lower portion of the second backside source/drain contact 721 may be away from a central line of the first source/drain region 321 towards the first diffusion break 401. In one embodiment, bottom surfaces of the first and the second backside source/drain contact 711 and 721 may be substantially coplanar.

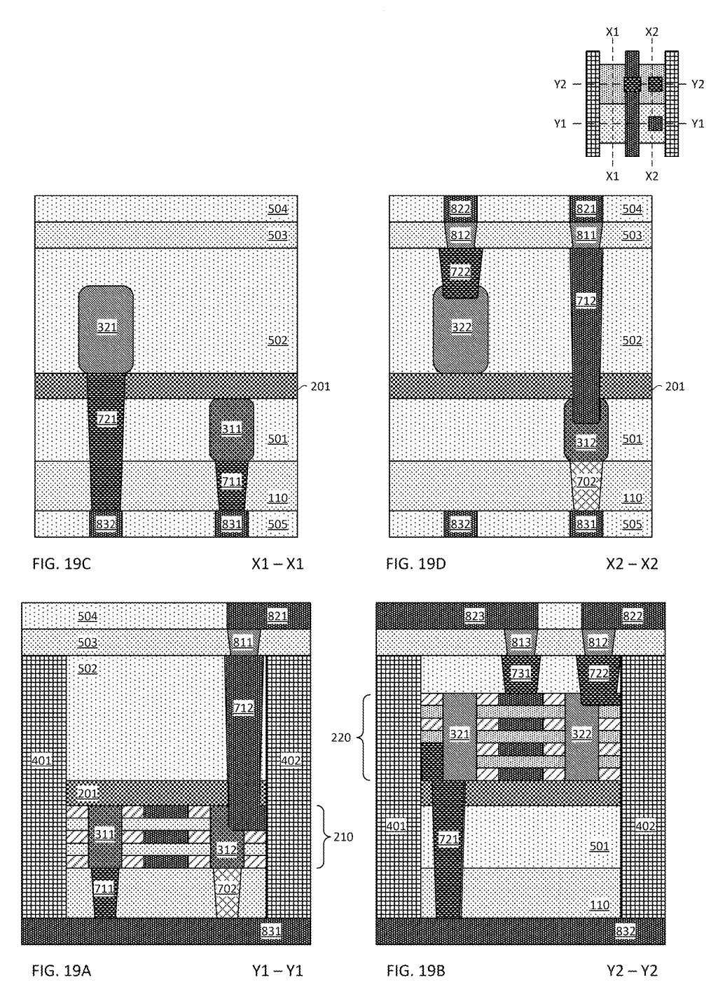

FIGS. 19A, 19B, 19C and 19D are demonstrative illustrations of various cross-sectional views of a semiconductor structure at a step of manufacturing thereof, following the step illustrated at FIGS. 18A, 18B, 18C and 18D, according to one embodiment of present invention. More particularly, embodiments of present invention provide forming a backside back-end-of-line (BBEOL) structure including one or more metal lines 831 and 832 embedded in a dielectric layer 505. The one or more metal lines 831 and 832 of the BBEOL structure may be formed through, for example, a damascene process or a subtractive patterning process. In one embodiment, in a memory structure such as a SRAM structure, the metal line 831 may serve as a VSS (or a VDD) and the metal line 832 may service as a VDD (or a VSS).

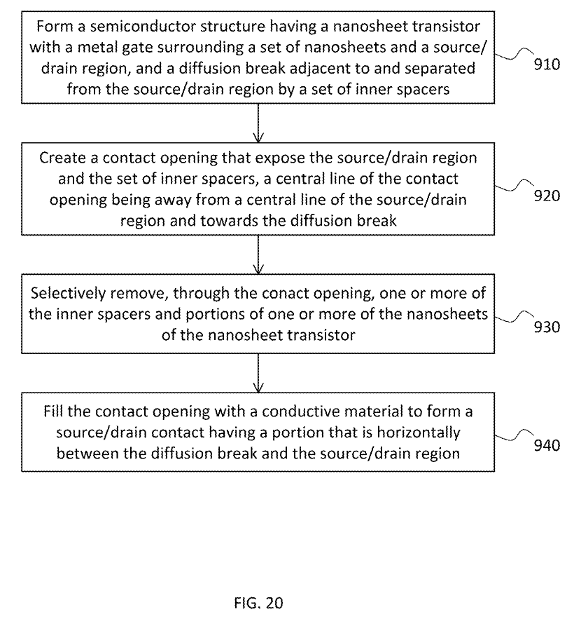

FIG. 20 is a demonstrative illustration of a flow-chart of a method of manufacturing a semiconductor structure according to embodiments of present invention. The method includes (910) forming a semiconductor structure having a nanosheet transistor with a metal gate surrounding a set of nanosheets and a source/drain region, and a diffusion break adjacent to and separated from the source/drain region by a set of inner spacers; (920) creating a contact opening that expose the source/drain region and the set of inner spacers, a central line of the contact opening being away from a central line of the source/drain region towards the diffusion break; (930) selectively removing, through the contact opening, one or more of the inner spacers and portions of one or more of the nanosheets of the nanosheet transistor; and (940) filling the contact opening with a conductive material to form a source/drain contact having a portion that is horizontally between the diffusion break and the source/drain region.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a nanosheet transistor having a metal gate surrounding a set of nanosheets; a source/drain region at an end surface of the set of nanosheets; and a set of inner spacers separating the source/drain region from the metal gate;
a diffusion break adjacent to and separated from the source/drain region by a distance equal to a length of the set of inner spacers; and
a frontside source/drain contact in contact with the source/drain region, the frontside source/drain contact having a lower portion at or below a top surface of the source/drain region and horizontally between the source/drain region and the diffusion break.

2. The semiconductor structure of claim 1, wherein the lower portion of the frontside source/drain contact has a width that is larger than the length of the set of inner spacers.

3. The semiconductor structure of claim 1, wherein the lower portion of the frontside source/drain contact has a height that is equal to or larger than a thickness of one of the inner spacers.

4. The semiconductor structure of claim 1, wherein the frontside source/drain contact has an upper portion above the top surface of the source/drain region, and a vertical central line of the upper portion of the frontside source/drain contact is away from a vertical central line of the source/drain region and situated towards the diffusion break.

5. The semiconductor structure of claim 1, wherein the diffusion break is a first diffusion break, further comprising:
a second diffusion break and a backside source/drain contact,
wherein the source/drain region is a first source/drain region of the nanosheet transistor, the nanosheet transistor further comprises a second source/drain region and the second diffusion break is adjacent to and separated from the second source/drain region by a distance equal to the length of the set of inner spacers; and wherein the backside source/drain contact is in contact with a bottom surface and a portion of a sidewall of the second source/drain region.

6. The semiconductor structure of claim 5, wherein the nanosheet transistor is a top nanosheet transistor and the frontside source/drain contact is a first frontside source/drain contact, further comprising:
a bottom nanosheet transistor having a metal gate surrounding a set of nanosheets and a first and a second source/drain region at end surfaces of the set of nanosheets of the bottom nanosheet transistor; and
a second frontside source/drain contact in contact with a top surface and a portion of a sidewall of the first source/drain region of the bottom nanosheet transistor.

7. The semiconductor structure of claim 6, wherein the second frontside source/drain contact has a bottom surface that is at or below at least one of the nanosheets of the bottom nanosheet transistor.

8. The semiconductor structure of claim 6, wherein at least a lower portion of the second frontside source/drain contact is in direct contact with the first diffusion break.

9. The semiconductor structure of claim 6, wherein the set of nanosheets of the bottom nanosheet transistor is at a level below, and does not vertically overlap entirely with, the set of nanosheets of the top nanosheet transistor.

10. The semiconductor structure of claim 6, wherein the backside source/drain contact is a first backside source/drain contact, further comprising a second backside source/drain contact in contact with a bottom surface of the second source/drain region of the bottom nanosheet transistor.

11. A semiconductor structure comprising:
a first nanosheet transistor having a metal gate surrounding a set of nanosheets; a first and a second source/drain region at end surfaces of the set of nanosheets; and a first and a second set of inner spacers separating the first and the second source/drain region, respectively, from the metal gate;
a first diffusion break adjacent to and separated from the first source/drain region by a third set of inner spacers; and
a first frontside source/drain contact in contact with the first source/drain region, the first frontside source/drain contact having a lower portion below a top surface of the first source/drain region and horizontally between the first source/drain region and the first diffusion break.

12. The semiconductor structure of claim 11, wherein the lower portion of the first frontside source/drain contact has a width that equals to a length of the third set of inner spacers.

13. The semiconductor structure of claim 11, wherein the lower portion of the first frontside source/drain contact has a height that is equal to or larger than a height of an inner spacer of the third set of inner spacers.

14. The semiconductor structure of claim 11, wherein a vertical central line of the top portion of the first source/drain contact is not aligned with a vertical central line of the first source/drain region.

15. The semiconductor structure of claim 11, further comprising:
a second diffusion break, the second diffusion break adjacent to and separated from the second source/drain region by a fourth set of inner spacers; and
a first backside source/drain contact in contact with a bottom surface of the second source/drain region.

16. The semiconductor structure of claim 15, further comprising:
a second nanosheet transistor having a metal gate surrounding a set of nanosheets and a first and a second source/drain region at end surfaces of the set of nanosheets of the second nanosheet transistor; and
a second frontside source/drain contact in contact with a top surface and a portion of a sidewall of the first source/drain region of the second nanosheet transistor,
wherein a top surface of the first frontside source/drain contact and a top surface of the second source/drain contact are substantially coplanar.

17. The semiconductor structure of claim 16, wherein the first and the second source/drain region of the second nanosheet transistor is at a level below, and does not vertically overlap entirely with, the first and the second source/drain region of the first nanosheet transistor.

18. The semiconductor structure of claim 16, wherein at least a portion of the second frontside source/drain contact is in directly contact with the first diffusion break.

19. The semiconductor structure of claim 16, further comprising a second backside source/drain contact in contact with a bottom surface of the second source/drain region of the second nanosheet transistor, wherein bottom surfaces of the first and the second backside source/drain contact are substantially coplanar.

20. A method of forming a semiconductor structure, comprising:
forming a nanosheet transistor having a metal gate surrounding a set of nanosheets and a source/drain region at an end surface of the set of nanosheets;
forming a diffusion break adjacent to and separated from the source/drain region by a set of inner spacers; and
forming a frontside source/drain contact in contact with the source/drain region, the frontside source/drain contact having a lower portion at or below a top surface of the source/drain region and horizontally between the source/drain region and the diffusion break.
